(19) United States
(12) Patent Application Publication
(10) Pub. No.: US 2024/0431165 A1
(43) Pub. Date: Dec. 26, 2024

(54) DISPLAY PANEL AND DISPLAY DEVICE

(71) Applicant: Xiamen Tianma Microelectronics Co., Ltd., Xiamen (CN)

(72) Inventor: Chaoqun WANG, Xiamen (CN)

(73) Assignee: Xiamen Tianma Microelectronics Co., Ltd., Xiamen (CN)

(21) Appl. No.: 18/824,528

(22) Filed: Sep. 4, 2024

(30) Foreign Application Priority Data
Oct. 10, 2023 (CN) 202311309253.2

(51) Int. Cl. H10K 59/131; G06F 3/041; G09G 3/20; H10K 59/126; H10K 59/40

(52) U.S. Cl. CPC H10K 59/131; G06F 3/0412; G09G 3/20; H10K 59/126; H10K 59/40; G06F 2203/04107; G09G 2310/0281; G09G 2310/0286; G09G 2310/0297; G09G 2320/0233; G09G 2354/00; G09G 2380/10

(57) ABSTRACT

Provided are a display panel and a display device. The display region includes an irregular bezel region. The boundary line between the irregular bezel region and a display region intersects the extension lines of data signal lines and the extension lines of scanning signal lines. The irregular bezel region includes a gate driver circuit region and a source driver circuit region. The source driver circuit region is located between the gate driver circuit region and the display region. A shift register circuit is configured in the gate driver circuit region. A demultiplexing circuit is configured in the source driver circuit region. The irregular bezel region also includes multiple data fan-out wires. The data fan-out wires, the shift register circuit, and the demultiplexing circuit are located in different film layers of the display panel respectively.

### CROSS-REFERENCE TO RELATED APPLICATION(S)

This application claims priority to Chinese Patent Application No. 202311309253.2 filed Oct. 10, 2023, the disclosure of which is incorporated herein by reference in its entirety.

### TECHNICAL FIELD

Embodiments of the present disclosure relate to the field of display technology and, in particular, to a display panel and a display device.

### BACKGROUND

With the diversification of display usage scenarios, the demand for irregular screens increases, such as in-vehicle electronic rear-view mirrors and other products. As the market and terminal audiences diversify, various irregular products emerge one after another. However, the existing irregular in-vehicle display product may be wide at the position of the irregular bezel and cannot satisfy the trend of narrow bezels.

### SUMMARY

The present disclosure provides a display panel and a display device to rationally lay out the structure of an irregular bezel region, implement the narrow bezel design of the irregular bezel region, and satisfy the trend of narrow bezels.

In a first aspect, an embodiment of the present disclosure provides a display panel. The display panel includes a display region and a non-display region. The non-display region and the display region are connected to each other. The display region includes multiple data signal lines and multiple scanning signal lines. The data signal lines intersect the scanning signal lines.

The non-display region includes an irregular bezel region. The boundary line between the irregular bezel region and the display region intersects the extension lines of the data signal lines and the extension lines of the scanning signal lines. The irregular bezel region includes a gate driver circuit region and a source driver circuit region. The source driver circuit region is located between the gate driver circuit region and the display region.

A shift register circuit is configured in the gate driver circuit region. The shift register circuit is electrically connected to the scanning signal lines and configured to provide a gate drive signal to the multiple scanning signal lines in sequence.

A demultiplexing circuit is configured in the source driver circuit region. The demultiplexing circuit is electrically connected to the data signal lines and configured to provide a data signal to the multiple data signal lines in sequence.

The irregular bezel region also includes multiple data fan-out wires. A data fan-out wire is electrically connected to at least two data signal lines through the demultiplexing circuit.

The data fan-out wires and the shift register circuit are located in different film layers of the display panel, and the data fan-out wires and the demultiplexing circuit are located in different film layers of the display panel. The projections of the data fan-out wires on the light emission surface of the display panel are overlapped with the projection of the shift register circuit and/or the projection of the demultiplexing circuit on the light emission surface of the display panel.

In a second aspect, an embodiment of the present disclosure provides a display device. The display device includes the display panel according to any one of the first aspect.

In the display panel and the display device provided by embodiments of the present disclosure, the irregular bezel region of the display panel includes a gate driver circuit region and a source driver circuit region. A shift register circuit is configured in the gate driver circuit region. The shift register circuit may provide a scanning signal to a pixel unit of the display region through a scanning signal line. A demultiplexing circuit is configured in the source driver circuit region. The demultiplexing circuit may receive a data signal according to the data fan-out wires configured in the irregular bezel region and provide the data signal to the pixel unit in the display region through a data signal line. Thus, the corresponding pixel unit in the display region is driven to implement the image display function. At the same time, the data fan-out wires are configured in a different film layer of the display panel from the shift register circuit and the demultiplexing circuit. The projections of the data fan-out wires are configured to are overlapped with the projection of the shift register circuit and/or the projection of the demultiplexing circuit. Thus, the data fan-out wires and the shift register circuit or the demultiplexing circuit may be vertically stacked up and down. In this manner, the data fan-out wires may be prevented from occupying excessive horizontal area of the irregular bezel region, and the horizontal spacing between the shift register circuit and demultiplexing circuit may be shortened, so that the horizontal width of the irregular bezel region may be effectively reduced, thereby implementing the design of a narrow bezel.

### BRIEF DESCRIPTION OF DRAWINGS

FIG. 1 is a diagram illustrating the structure of a display panel in the related art.

FIG. 2 is a partial enlarged view of an irregular bezel region of the display panel shown in FIG. 1.

FIG. 3 is a section view of the irregular bezel region of the display panel shown in FIG. 2.

FIG. 4 is a partial view illustrating the structure of a display panel according to an embodiment of the present disclosure.

FIG. 5 is a section view illustrating the partial structure of the display panel shown in FIG. 4.

FIG. 6 is a partial view illustrating the structure of a display panel according to an embodiment of the present disclosure.

FIG. 7 is a section view illustrating the partial structure of the display panel shown in FIG. 6.

FIG. 8 is a section view illustrating the partial structure of another display panel according to an embodiment of the present disclosure.

FIG. 9 is a partial view illustrating the structure of another display panel according to an embodiment of the present disclosure.

FIGS. 10 and 11 are section views illustrating the partial structures of another two display panels according to an embodiment of the present disclosure.

FIG. 12 is a diagram illustrating the structure of another display panel according to an embodiment of the present disclosure.

FIG. 13 is a partial enlarged view of the display panel shown in FIG. 12.

FIG. 14 is a section view illustrating the partial structure of the display panel shown in FIG. 12.

FIG. 15 is a section view illustrating the partial structure of another display panel according to an embodiment of the present disclosure.

FIG. 16 is a partial view illustrating the structure of another display panel according to an embodiment of the present disclosure.

FIG. 17 is a section view illustrating the partial structure of the display panel shown in FIG. 16.

FIGS. 18 and 19 are section views illustrating the partial structures of another two display panels according to an embodiment of the present disclosure.

FIG. 20 is a section view illustrating the partial structure of another display panel according to an embodiment of the present disclosure.

FIG. 21 is a diagram illustrating the structure of a display device according to an embodiment of the present disclosure.

### DETAILED DESCRIPTION

Hereinafter the present disclosure is further described in detail in conjunction with the drawings and embodiments. It is to be understood that the specific embodiments described herein are intended to illustrate and not to limit the present disclosure. Additionally, it is to be noted that, for ease of description, only part, not all, of structures related to the present disclosure are illustrated in the drawings.

Terms used in the embodiments of the present disclosure are merely used to describe the specific embodiments and not intended to limit the present disclosure. It is to be noted that spatially related terms, including “on”, “below”, “left” and “right” used in the embodiments of the present disclosure, are described from the perspective of the drawings, and are not to be construed as a limitation to the present disclosure. In addition, in the context, it is to be understood that when a component is formed “on” or “below” another component, the component may not only be directly formed “on” or “below” another component, and may also be indirectly formed “on” or “below” another component via an intermediate component. The terms “first” and “second” are merely used for description and used to distinguish between different components rather than indicate any order, quantity, or importance. For those of ordinary skill in the art, specific meanings of the preceding terms in the present disclosure may be understood based on specific situations.

The term “comprising” and its variations used in the present disclosure are open-ended, that is, “including but not limited to”. The term “based on” refers to “at least partially based on”. The term “an embodiment” refers to “at least one embodiment.”

It is to be noted that concepts such as “first” and “second” mentioned in the present disclosure are only used to distinguish corresponding contents, and are not used to limit the sequence or interdependence relationship.

It is to be noted that the modifications of “one” and “multiple” mentioned in the present disclosure are illustrative and not limited, and it is to be understood by those skilled in the art that unless the context clearly indicates otherwise, “one” or “multiple” should be understood as “one or more”.

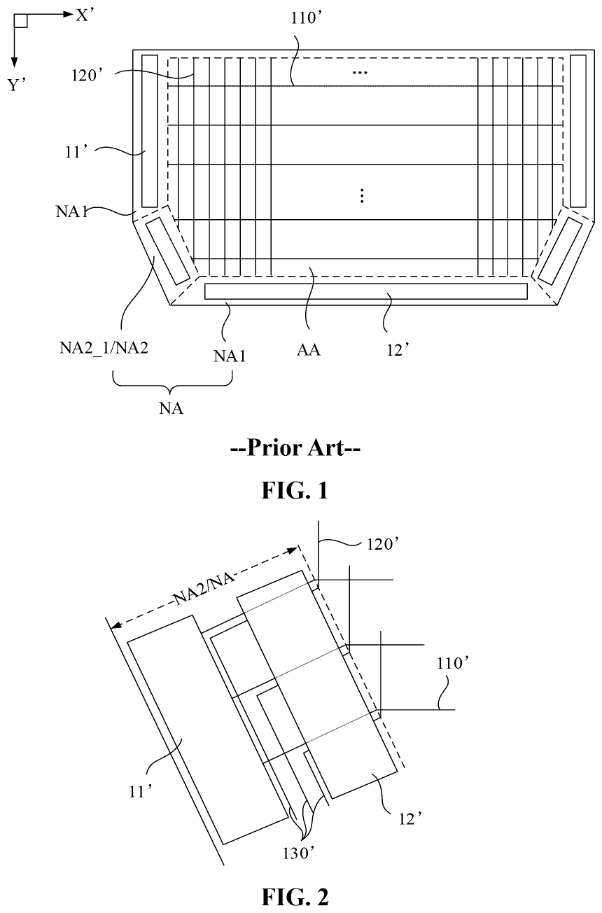

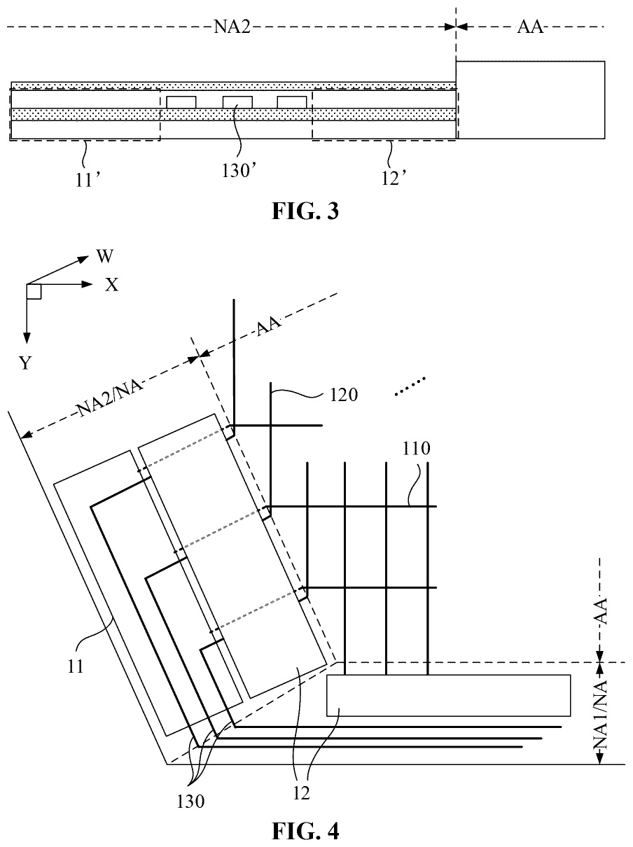

FIG. 1 is a diagram illustrating the structure of a display panel in the related art. FIG. 2 is a partial enlarged view of an irregular bezel region of the display panel shown in FIG. 1. FIG. 3 is a section view of the irregular bezel region of the display panel shown in FIG. 2. Referring to FIGS. 1 to 3, first, those skilled in the art know that multiple data signal lines 120′ and multiple scanning signal lines 110′ may be configured in the display region AA of the display panel, and the data signal lines 120′ and the scanning signal lines 110′ are intersected with each other. The data signal lines 120′ extend in a column direction Y′, and the scanning signal lines 110′ extend in a row direction Y′. Based on this, a regular bezel region NA1 and an irregular bezel region NA2 are defined in the existing irregular display panel. The boundary line between the regular bezel region NA1 and the display region AA intersects only a data signal line 120′ or a scanning signal line 110′ of the display region AA. Thus, the bezel region needs to be provided with only a driver circuit that provides a signal to the data signal line 120′ or the scanning signal line 110′, that is, only one type of driver circuit is configured. The boundary line between the irregular bezel region NA2 and the display region AA intersects both the data signal line 120′ and the scanning signal line 110′ of the display region AA, for example, the irregular bezel region NA2_1 shown in FIG. 1. At this time, since it is necessary to provide signals to the data signal line 120′ and the scanning signal line 110′ respectively, it is necessary to provide two types of driver circuits, that is, the source driver circuit 12′ and the gate driver circuit 11′ in the irregular bezel region NA2_1 as shown in FIG. 2. In addition, to implement different functions such as VT testing and touching, a VT test circuit and a touch wire (not shown) are also configured in the irregular bezel region NA2 in the related art. In addition, as shown in FIGS. 2 and 3, for the irregular bezel region NA2, it is necessary not only to dispose the source driver circuit 12′, the gate driver circuit 11′, the VT test circuit, and the touch wire, but also to lay out data fan-out wires 130′ to provide a data signal to each source driver circuit 12′.

At present, for the structural layout of the irregular bezel region NA2, referring to FIGS. 2 and 3, the data fan-out wires 130′ are generally configured between the source driver circuit 12′ and the gate driver circuit 11′ in a horizontal side-by-side arrangement. Thus, compared with the regular bezel region NA1, in one aspect, due to the large number of circuit structures in the irregular bezel region NA2, and in another aspect, due to the horizontal layout between circuits and some wires, the area of the irregular bezel region NA2 is larger, and the width of the bezel is too wide, which is not conducive to the design of a narrow bezel.

In response to the preceding technical problems, an embodiment of the present disclosure provides a display panel. The display panel includes a display region and a non-display region. The non-display region and the display region are connected to each other. The display region includes multiple data signal lines and multiple scanning signal lines. The data signal lines intersect the scanning signal lines.

The non-display region includes an irregular bezel region. The boundary line between the irregular bezel region and the display region intersects the extension lines of the data signal lines and the extension lines of the scanning signal lines. The irregular bezel region includes a gate driver circuit region and a source driver circuit region. The source driver circuit region is located between the gate driver circuit region and the display region.

A shift register circuit is configured in the gate driver circuit region. The shift register circuit is electrically connected to the scanning signal lines and configured to provide a gate drive signal to the multiple scanning signal lines in sequence.

A demultiplexing circuit is configured in the source driver circuit region. The demultiplexing circuit is electrically connected to the data signal lines and configured to provide a data signal to the multiple data signal lines in sequence.

The irregular bezel region also includes multiple data fan-out wires. A data fan-out wire is electrically connected to at least two data signal lines through the demultiplexing circuit.

The data fan-out wires and the shift register circuit are located in different film layers of the display panel, and the data fan-out wires and the demultiplexing circuit are located in different film layers of the display panel. The projections of the data fan-out wires on the light emission surface of the display panel are overlapped with the projection of the shift register circuit and/or the projection of the demultiplexing circuit on the light emission surface of the display panel.

In the preceding technical solutions, the irregular bezel region of the display panel includes a gate driver circuit region and a source driver circuit region. A shift register circuit is configured in the gate driver circuit region. The shift register circuit may provide a scanning signal to a pixel unit of the display region through a scanning signal line. A demultiplexing circuit is configured in the source driver circuit region. The demultiplexing circuit may receive a data signal according to the data fan-out wires configured in the irregular bezel region and provide the data signal to the pixel unit in the display region through a data signal line. Thus, the corresponding pixel unit in the display region is driven to implement the image display function. At the same time, the data fan-out wires are configured in a different film layer of the display panel from the shift register circuit and the demultiplexing circuit. The projections of the data fan-out wires are configured to are overlapped with the projection of the shift register circuit and/or the projection of the demultiplexing circuit. Thus, the data fan-out wires and the shift register circuit or the demultiplexing circuit may be vertically stacked up and down. In this manner, the data fan-out wires may be prevented from occupying excessive horizontal area of the irregular bezel region, and the horizontal spacing between the shift register circuit and demultiplexing circuit may be shortened, so that the horizontal width of the irregular bezel region may be effectively reduced, thereby implementing the design of a narrow bezel.

The above is the core concept of the present disclosure, and the technical solutions in the embodiments of the present disclosure are described clearly and completely hereinafter in conjunction with the drawings in the embodiments of the present disclosure. Based on the embodiments of the present disclosure, all other embodiments obtained by those of ordinary skill in the art without creative work are within the scope of the present disclosure.

FIG. 4 is a partial view illustrating the structure of a display panel according to an embodiment of the present disclosure. FIG. 5 is a section view illustrating the partial structure of the display panel shown in FIG. 4. Referring to FIGS. 4 and 5, the display panel includes a display region AA and a non-display region NA. The non-display region NA and the display region AA are connected to each other. The display region AA includes multiple data signal lines 120 and multiple scanning signal lines 110. The data signal lines 120 intersect the scanning signal lines 110.

The non-display region NA includes an irregular bezel region NA2. The boundary line between the irregular bezel region NA2 and the display region AA intersects the extension lines of the data signal lines 120 and the extension lines of the scanning signal lines 110. The irregular bezel region NA2 includes a gate driver circuit region and a source driver circuit region (not shown). The source driver circuit region is located between the gate driver circuit region and the display region AA.

A shift register circuit is configured in the gate driver circuit region 11. The shift register circuit 11 is electrically connected to the scanning signal lines 110 and configured to provide a gate drive signal to the multiple scanning signal lines 110 in sequence.

A demultiplexing circuit is configured in the source driver circuit region 12. The demultiplexing circuit 12 is electrically connected to the data signal lines 120 and configured to provide a data signal to the multiple data signal lines 120 in sequence.

The irregular bezel region NA2 also includes multiple data fan-out wires 130. A data fan-out wire 130 is electrically connected to at least two data signal lines 120 through the demultiplexing circuit 12.

The data fan-out wires 130 and the shift register circuit 11 are located in different film layers of the display panel, and the data fan-out wires 130 and the demultiplexing circuit 12 are located in different film layers of the display panel. The projections of the data fan-out wires 130 on the light emission surface of the display panel are overlapped with the projection of the shift register circuit 11 and/or the projection of the demultiplexing circuit 12 on the light emission surface of the display panel.

The scanning signal lines 110 in the display region AA extend in a first direction X (the row direction in the example) and are arranged in a second direction Y (the column direction in the example). The data signal lines 120 extend in the second direction Y (the column direction in the example) and are arranged in the first direction X (the row direction in the example). It should be understood by those skilled in the art that multiple scanning signal line 110 and multiple data signal line 120 in the display region AA intersect to form multiple pixel units (not shown). The scanning signal lines 110 provide a scanning signal to the pixel units, and the data signal lines 120 provide a data signal to the pixel units, thereby driving each pixel unit of the display region to light up one by one to implement the display of the entire image. Based on this, as described above, for an irregular display panel, the bezel region NA may be divided into a regular bezel region NA1 and an irregular bezel region NA2. The junction line between the regular bezel region NA1 and display region AA intersects only the scanning signal lines 110 or the data signal lines 120. Thus, the shift register circuit 11 for the scanning signal lines 110 or the demultiplexing circuit 12 for the data signal lines 120 may be configured in the regular bezel region NA1. The regular bezel region NA1 is generally located on two sides of the display region AA in the first direction X or the second direction Y For the irregular bezel region NA2, the junction line between the irregular bezel region NA2 and display region AA intersects the scanning signal lines 110 and the data signal lines 120, that is, the demultiplexing circuit 12 and the shift register circuit 11 need to be configured for the data signal lines 120 and the scanning signal line 110 respectively. The irregular bezel region NA2 is generally located at the junction of two types of regular bezel regions NA1. The difference between the two types of regular bezel regions NA1 is that one regular bezel region NA1 is located on one side of the display region AA in the first direction X, and the other regular bezel region NA1 is located on one side of the display region AA in the second direction Y To simplify, the irregular bezel region NA2 may be understood as a bezel region at the corner position of the display region AA.

In this embodiment of the present disclosure, for the circuit and wiring layout in the irregular bezel region NA2, the data fan-out wires 130 that provide a data signal to the demultiplexing circuit 12 are configured in a different film layer of the display panel from the shift register circuit 11 and the demultiplexing circuit 12. The projections of the data fan-out wires 130 on the light emission surface of the display panel are overlapped with the projection of the shift register circuit 11 and/or the projection of the demultiplexing circuit 12 on the light emission surface of the display panel. Actually, the data fan-out wires 130 are moved vertically above the shift register circuit 11 and/or the demultiplexing circuit 12. In FIG. 4, for example, the data fan-out wires 130 are configured above the shift register circuit 11. Thus, the data fan-out wires 130 and the shift register circuit 11 or the demultiplexing circuit 12 may be vertically stacked up and down. The problem of excessive spacing between the shift register circuit 11 and the demultiplexing circuit 12 in a horizontal direction when the data fan-out wires 130 are configured between the shift register circuit 11 and the demultiplexing circuit 12 is avoided. The horizontal spacing between the shift register circuit and demultiplexing circuit may be shortened, so that the horizontal width of the irregular bezel region may be effectively reduced. In this manner, the data fan-out wires 130 may be prevented from occupying excessive horizontal area of the irregular bezel region NA2, thereby implementing the design of a narrow bezel. The vertical direction here refers to the direction perpendicular to the plane formed by the intersection of the first direction X and the second direction Y, that is, the Z direction shown in FIG. 5. The horizontal direction refers to the direction parallel to the plane formed by the intersection of the first direction X and the second direction Y, for example, the W direction shown in FIG. 4.

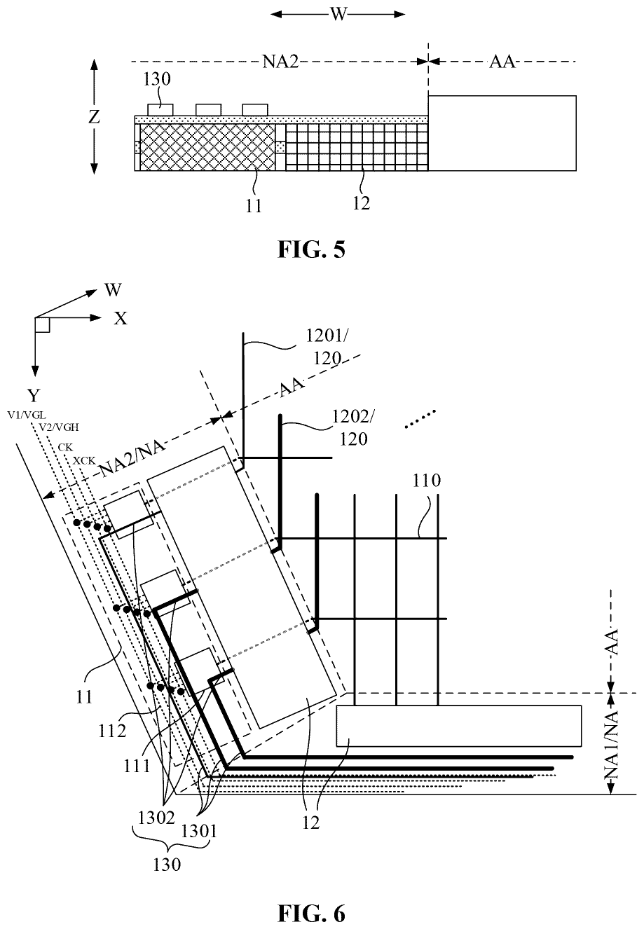

FIG. 6 is a partial view illustrating the structure of a display panel according to an embodiment of the present disclosure. FIG. 7 is a section view illustrating the partial structure of the display panel shown in FIG. 6. Referring to FIG. 6, first, the shift register circuit 11 includes multiple shift registers 111 and multiple first signal wires 112. The multiple shift registers 111 are cascaded in sequence. The multiple first signal wires 112 extend in parallel and located on the side of the shift registers 111 facing away from the display region AA. A shift register 111 is electrically connected to at least one first signal wire 112. Referring to FIG. 7, optionally, the projections of the data fan-out wires 130 on the light emission surface of the display panel are overlapped with the projections of the shift registers 111 and/or the projections of the first signal wires 112 on the light emission surface of the display panel. In FIG. 7, for example, data fan-out wires 130 are configured above the shift registers 111 and the first signal wires 112.

First, it is to be noted that for example, in the structural diagram shown in FIG. 6, the signal wires and the connection lines are denoted by dotted lines, solid lines, and thickened solid lines, which are only used to distinguish between different signal lines and do not represent the actual widths and actual shapes of the signal lines. In the subsequent diagrams, the signal wires and the connection lines are distinguished in this manner, and no further explanation is given later.

It should be understood by those skilled in the art that the shift register circuit 11 needs to sequentially provide scanning signals to the scanning signal lines 110 row by row. To implement the process of row-by-row scanning, the shift register circuit 11 needs to sequentially output scanning signals through the cascaded shift registers 111. Among the cascaded shift registers 111, the first shift register 111 receives a trigger signal STV and generates a scanning signal and simultaneously outputs the scanning signal to the correspondingly connected scanning signal line 110 and the shift register 111 of the next level. The shift register 111 of the next level shifts the scanning signal to generate the second-level scanning signal and simultaneously outputs the scanning signal to the correspondingly connected scanning signal line 110 and the shift register 111 of the next level, and the rest are done in the same manner. Thus, the scanning process of all scanning signal lines 110 is implemented. The first signal wires 112 in the shift register circuit 11 may be understood as a clock signal, a level signal, and a trigger signal STV required during the working process of the shift register circuit 11. For example, the clock signal may include both CK and XCK. In other shift register circuit designs, only one clock signal CK or more clock signals may be configured. This is not limited in this embodiment. The level signal may include a high-level signal VGH and a low-level signal VGL. Thus, for multiple shift registers 111 in cascade, it is necessary to arrange the first signal wires 112 on the side facing away from the display region AA to provide clock signals, level signals, and trigger signals to the shift registers 111.

In summary, it can be seen that for the shift register circuit 11, the region in which the shift register circuit 11 is located may be divided into a region in which the shift registers 111 are located and a region in which the first signal wires 112 are located. Based on this, in an embodiment of the present disclosure, the projections of the data fan-out wires 130 on the light emission surface of the display panel is configured to are overlapped with the projections of the shift registers 111 and/or the projections of the first signal wires 112 on the light emission surface of the display panel. Essentially, the data fan-out wires 130 are configured in a region in which the shift registers 111 are located, and the data fan-out wires 130 and the shift registers 111 are vertically stacked up and down. Alternatively, the data fan-out wires 130 are configured in a region in which the first signal wires 112 are located, and the data fan-out wires 130 and the first signal wires 112 are vertically stacked up and down. Alternatively, part of the data fan-out wires 130 are configured in the region in which the shift registers 111 are located, and the part of the data fan-out wires 130 and the shift registers 111 are vertically stacked up and down. Part of the data fan-out wires 130 are configured in the region in which the first signal wires 112 are located, and the part of the data fan-out wires 130 and the first signal wires 112 are vertically stacked up and down.

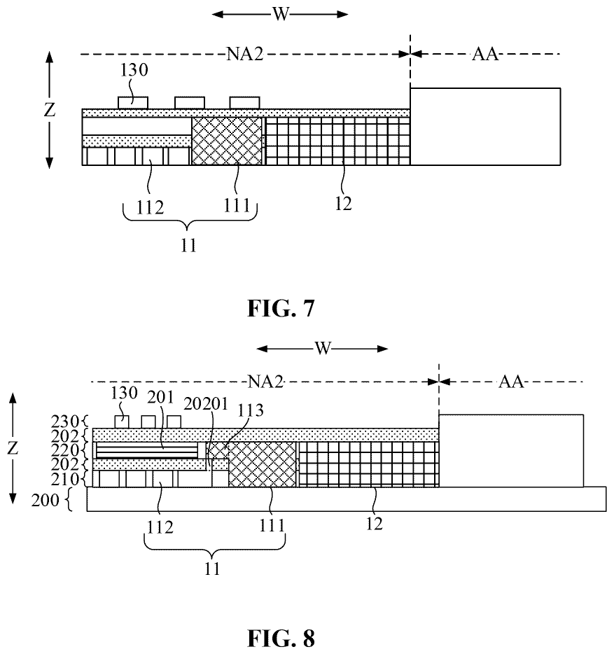

The specific disposition positions of the data fan-out wires 130 and the corresponding optimized design are further described below. FIG. 8 is a section view illustrating the partial structure of another display panel according to an embodiment of the present disclosure. Referring to FIG. 8, optionally, the projections of the data fan-out wires 130 on the light emission surface of the display panel are overlapped with the projections of the first signal wires 112 on the light emission surface of the display panel. The data fan-out wires 130 and the first signal wires 112 are located in different film layers of the display panel, and a signal shielding layer 201 is configured between the film layer where the data fan-out wires 130 are located and the film layer where the first signal wires 112 are located.

The data fan-out wires 130 are electrically connected to the demultiplexing circuit 12 and are responsible for providing data signals to the demultiplexing circuit 12. The first signal wires 112 include clock signal lines and trigger signal lines and are responsible for providing pulse signals such as clock signals and trigger signals to the shift registers. Apparently, when the data fan-out wires 130 and the first signal wires 112 are configured to be vertically stacked up and down, the voltage variation of the signals on the first signal wires 112 may cause capacitive coupling with the data fan-out wires 130. The clock signal having a higher frequency and the trigger signal having a higher frequency may interfere with the data signal transmitted on the data fan-out wires 130. As a result, there is a deviation in the data signal, which causes bright and dark lines to appear on a display image, thereby affecting the accuracy of the pixel display. Based on this, in this embodiment, the data fan-out wires 130 and the first signal wires 112 are configured in different film layers of the display panel, and the signal shielding layer 201 is configured between the film layer where the data fan-out wires 130 are located and the film layer where the first signal wires 112 are located. The interference of high-frequency signals such as clock signals and trigger signals in the first signal wires 112 to the data signals transmitted on the data fan-out wires 130 may be shielded by the signal shielding layer 201. Thus, the normal transmission of the data signals on the data fan-out wires 130 may be ensured, and it is ensured that signals of the shift register circuit and signals of the data fan-out wires are independent of each other. In this manner, the accuracy of the pixel display is improved, and the problem of uneven display of a display image caused by bright and dark lines is solved, thereby ensuring the display quality of the display panel.

Further referring to FIG. 8, in a specific embodiment, the display panel also includes a base substrate 200, a first metal layer 210, a second metal layer 220, and a third metal layer 230. In a direction perpendicular to a plane where the base substrate 200 is located and away from the base substrate 200, the first metal layer 210, the second metal layer 220, and the third metal layer 230 are distributed on one side of the base substrate 200 in sequence. An interlayer insulating layer 202 is configured between two adjacent layers of the first metal layer 210, the second metal layer 220, and the third metal layer 230. The data fan-out wires 130 are located in the third metal layer 230. The first signal wires 112 are located in the first metal layer 210. The signal shielding layer 201 is located in the second metal layer 220.

The first metal layer 210, the second metal layer 220, and the third metal layer 230 are basic metal layers for preparing circuits and wires for the display panel. The metal layers are patterned, so that wires and connection lines between circuit components may be formed. The data fan-out wires 130 are prepared in the third metal layer 230. The first signal wires are prepared in the first metal layer 210. The signal shielding layer 201 between the data fan-out wires 130 and the first signal wires 112 may be prepared in the second metal layer 220 between the third metal layer 230 and the first metal layer 210. It is to be understood that part of the second metal layer 220 is multiplexed into the signal shielding layer 201, so that the addition of a metal layer to the signal shielding layer 201 alone may be avoided. Further, the preparation process and the preparation technique of the display panel may be simplified, and on the premise that the signal shielding layer 201 is used to shield the data fan-out wires 130 from interference, the manufacturing costs can be saved.

Further referring to FIG. 8, more specifically, the shift register circuit 11 also includes multiple first connection wires 113 located in the second metal layer 220. One end of a first connection wire 113 is electrically connected to a shift register 111, and the other end of the first connection wire 113 is electrically connected to a first signal wire 112 through a first via 20201. The first via 20201 is located in an interlayer insulating layer 202 between the first metal layer 210 and the second metal layer 220. The projection of the signal shielding layer 201 on the light emission surface of the display panel does not overlap projections of the first connection wires 113 on the light emission surface of the display panel.

Here, the first connection wires 113 are mainly responsible for providing the signals to the first signal wires 112 to the shift registers 111. Since the first signal wires 112 are configured in the first metal layer 210, the components of the shift registers 111 that receive the signals transmitted by the first signal wires 112 are generally transistors, and the source and drain or gate thereof are generally configured in the second metal layer 220. When the first signal wires 112 and the shift registers 111 are connected, it is necessary to configure the first connection wires 113 and the first via 20201 to span two metal layers. Of course, it can also be understood that to avoid the influence of the signal shielding layer 201 of the same layer, when the first signal wires 112 are configured, the first signal wires 112 need to be insulated from the signal shielding layer 201. That is, when the second metal layer 220 is prepared, the first connection wires 113 and the pattern of the signal shielding layer 201 need to be separated by patterning.

Furthermore, to implement a better shielding effect, for example, in the preceding embodiment, for the signal shielding layer 201 between the data fan-out wires 130 and the first signal wires 112, a fixed potential signal may be introduced into the signal shielding layer 201.

Specifically, referring to FIG. 6, in an embodiment of the present disclosure, the first signal wires 112 include first level signal lines V1 and second level signal lines V2. The potential on a first level signal line V1 is less than the potential on a second level signal line V2. The first level signal lines V1 or the second level signal lines V2 may be electrically connected to the signal shielding layer 201. The first level signal lines V1 may be understood as low-level signal lines VGL in the shift register circuit 11. The second level signal lines V2 may be understood as high-level signal lines VGH in the shift register circuit 11. In this embodiment, essentially, the logic high-level signal or logic low-level signal in the shift register circuit 11 is introduced into the signal shielding layer 201 to stabilize the potential of the signal shielding layer 201. It should be added that according to the section view shown in FIG. 8, when the first level signal lines V1 or the second level signal lines V2 in the first signal wires 112 introduce fixed level signals into the signal shielding layer 201, the interlayer insulating layer 202 between the first metal layer 210 and the second metal layer 220 may be punched, so that the signal shielding layer 201 is electrically connected to the first level signal lines V1 or the second level signal lines V2. In this manner, fixed signals are introduced.

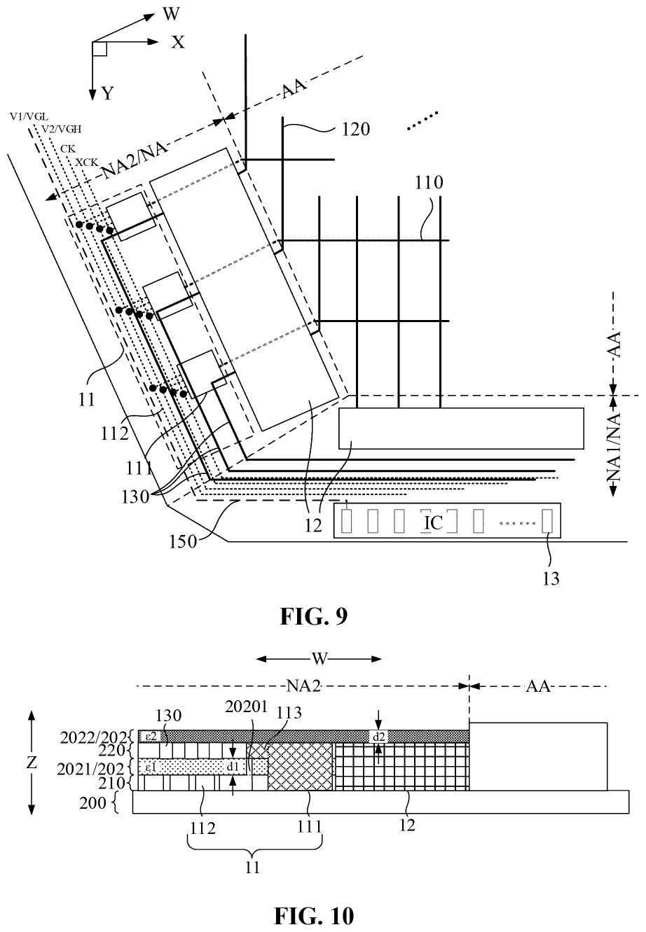

FIG. 9 is a partial view illustrating the structure of another display panel according to an embodiment of the present disclosure. Referring to FIGS. 8 and 9, in another embodiment of the present disclosure, the non-display region NA also includes a bonding pad 13 and a fixed potential signal line 150. The bonding pad 13 is configured to bond a driver chip IC. One end of the fixed potential signal line 150 is electrically connected to the signal shielding layer 201, and the other end of the fixed potential signal line 150 is electrically connected to the driver chip IC through the bonding pad 13. The driver chip IC is configured to provide the fixed potential signal to the signal shielding layer 201 through the fixed potential signal line 150.

In the preceding two embodiments, a fixed potential signal is introduced into the signal shielding layer 201, so that the signal shielding layer 201 may have a stable potential. Thus, the electromagnetic interference generated by a high-frequency signal is shielded, so that the signal shielding layer 201 can effectively block the electromagnetic interference generated by the first signal wires 112 to the data fan-out wires 130, and the signal interference problem caused by the capacitive coupling between signal lines can be effectively solved.

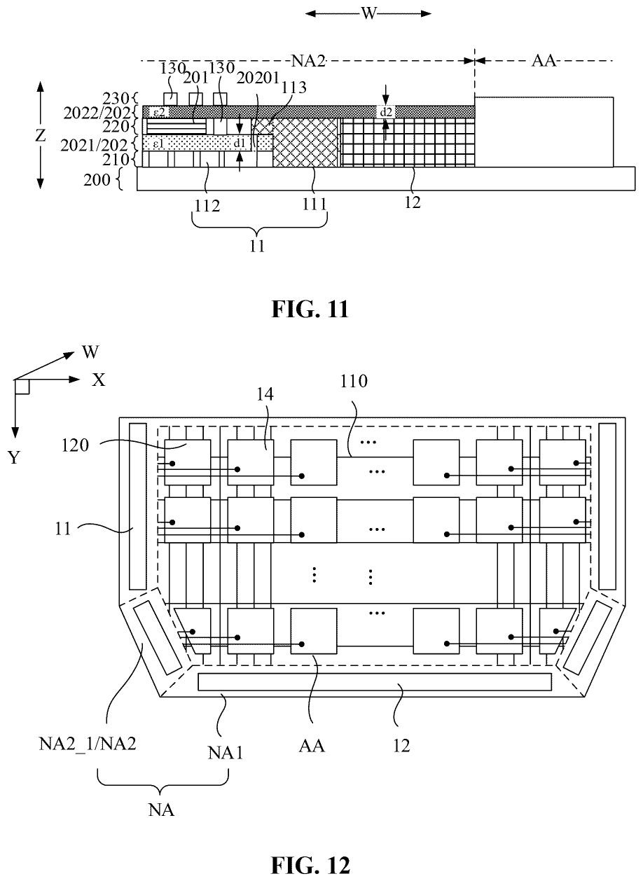

FIGS. 10 and 11 are section views illustrating the partial structures of another two display panels according to an embodiment of the present disclosure. Referring to FIGS. 10 and 11, the display panel also includes a base substrate 200, a first metal layer 210, a second metal layer 220, and a third metal layer 230. In the direction perpendicular to a plane where the base substrate 200 is located and away from the base substrate 200, the first metal layer 210, the second metal layer 220, and the third metal layer 230 are distributed on the side of the base substrate 200 in sequence. The interlayer insulating layer 202 is configured between two adjacent layers of the first metal layer 210, the second metal layer 220, and the third metal layer 230. The first signal wires 112 are located in the first metal layer 210. At least part of the data fan-out wires 130 are located in the second metal layer 220.

Specifically, the data fan-out wires 130 may be all configured in the second metal layer 220 as shown in FIG. 10, or may be partially configured in the second metal layer 220 and partially configured in the third metal layer 230 as shown in FIG. 11. In this embodiment, at least part of the data fan-out wires 130 are configured in the second metal layer 220. The essence is also to stack the data fan-out wires 130 above or under the first signal wires 112 located in the first metal layer 210. In this manner, the data fan-out wires 130 are prevented from occupying the horizontal area of the irregular bezel region NA2, which is conducive to the design of a narrow bezel. The embodiment shown in FIG. 11 is designated for the case where the number of first signal wires 112 is small, and the number of data fan-out wires 130 is large. It is to be understood that in this case, when all the data fan-out wires 130 are configured in the third metal layer 230 and above the first signal wires 112, the width of the region in which the first signal wires 112 are located in the horizontal direction cannot satisfy the layout of all the data fan-out wires 130, and part of the data fan-out wires 130 may be configured in the second metal layer 220. Moreover, as shown in FIG. 11, in the region where data fan-out wires 130 are not configured in the second metal layer 220, the signal shielding layer 201 may also be configured to isolate the capacitive coupling of the first signal wires 112 of the first metal layer 210 and the data fan-out wires 130 of the third metal layer 230.

In addition, as described above, since a high-frequency clock signal or a high-frequency trigger signal needs to be transmitted on the first signal wires 112, when the data fan-out wires 130 and the first signal wires 112 are configured to be vertically stacked up and down, capacitive coupling is easily generated between the wires, and electromagnetic interference is generated to the data fan-out wires 130. Thus, when at least part of the data fan-out wires 130 are configured in the second metal layer 220, and at least part of the data fan-out wires 130 and the first signal wires 112 are vertically stacked up and down, it is also necessary to overcome the capacitive coupling problem of part of the data fan-out wires 130 and the first signal wires 112.

Specifically, further referring to FIGS. 10 and 11, the interlayer insulating layer 202 includes a first interlayer insulating layer 2021 and a second interlayer insulating layer 2022. The first interlayer insulating layer 2021 is located between the first metal layer 210 and the second metal layer 220. The second interlayer insulating layer 2022 is located between the second metal layer 220 and the third metal layer 230. The thickness d1 of the first interlayer insulating layer 2021 is greater than the thickness d2 of the second interlayer insulating layer 2022; and/or the dielectric constant ε1 of the first interlayer insulating layer 2021 is less than the dielectric constant ε2 of the second interlayer insulating layer 2022.

Those skilled in the art know that the capacitance formula is C=εA/d. C is directly proportional to the dielectric constant ε and inversely proportional to the thickness d of the dielectric layer between capacitor plates. In this embodiment, essentially, the thickness d of the first interlayer insulating layer 2021 between the data fan-out wires 130 in the second metal layer 220 and the first signal wires 112 in the first metal layer 210 is thickened, so that the capacitance between two wires is reduced, thereby avoiding the capacitive coupling between the two wires. Similarly, the dielectric constant ε of the first interlayer insulating layer 2021 between the data fan-out wires 130 in the second metal layer 220 and the first signal wires 112 in the first metal layer 210 is set smaller. Similarly, the capacitance between two wires is reduced, thereby avoiding the capacitive coupling between the two wires.

It is to be understood that the thickness of the first interlayer insulating layer 2021 is increased, and the dielectric constant of the first interlayer insulating layer 2021 is reduced, so that the capacitance may be better reduced, thereby avoiding the capacitive coupling between two wires. Those skilled in the art may make selections and configuration according to actual requirements. In addition, it should be added that the first interlayer insulating layer 2021 may be made of a different insulating material from the second interlayer insulating layer 2022 to implement the purpose of reducing the dielectric constant.

It is to be noted that in the actual application process, since the components in the shift register 111 may occupy the first metal layer 210 and the second metal layer 220, when part of the data fan-out wires 130 are laid out in the second metal layer 220, they may be laid above the first signal wires 112, that is, the data fan-out wires 130 in the second metal layer 220 may be configured not to are overlapped with the projections of the shift registers 111 but to are overlapped with the projections of the first signal wires 112.

Further referring to FIG. 6, the data fan-out wires include first wire segments 1301. The extension direction of the first wire segments 1301 is parallel to the extension direction of the junction line between the irregular bezel region NA2 and the display region AA. In a specific embodiment, the projections of first wire segments 1301 of part of the data fan-out wires 1301 on the light emission surface of the display panel may be configured to be overlapped with the projections of the shift registers 111 on the light emission surface of the display panel. The projections of first wire segments 1301 of part of the data fan-out wires 130 on the light emission surface of the display panel are overlapped with the projections of the first signal wires 112 on the light emission surface of the display panel. The data signal lines 120 include first data signal lines 1201 and second data signal lines 1202. A data fan-out wire 130 of which the projection of a first wire segment 1301 overlaps the projection of a first signal wire 112 is electrically connected to a first data signal line 1201 through the demultiplexing circuit 12. A data fan-out wire 1301 of which the projection of a first wire segment 1301 overlaps the projection of a shift register 111 is electrically connected to a second data signal line 1202 through the demultiplexing circuit 12. In the first direction X, the first data signal lines 1201 are located on the side of the second data signal lines 1202 adjacent to the irregular bezel region NA2. The first direction X is the arrangement direction of multiple data signal lines 120.

First, it is to be noted that the extension direction of the first wire segments 1301 in the data fan-out wires 130 is parallel to the extension direction of the junction line between the irregular bezel region NA2 and the display region AA, which means that there are partial wire segments in each data fan-out wire 130 that extend in parallel and are arranged in the W direction as shown in the figure. Of course, to electrically connect the data fan-out wires 130 to the demultiplexing circuit 12, second wire segments 1302 are configured in the data fan-out wires 130. The second wire segments 1302 extend in the W direction, and two ends of a second wire segment 1302 are connected to a first wire segment 1301 and the demultiplexing circuit 12 respectively. It can be seen that multiple first wire segments 1301 arranged in the W direction may be configured to partially overlap first signal wires 112 and partially overlap shift registers 111. That is, part of the first wire segments 1301 may be configured above the region where the first signal wires 112 are located, and part of the first wire segments 1301 may be configured above the region where the shift registers are located.

It is to be understood that since the first signal wires 112 are located on the side of the shift registers 111 facing away from the display region AA, compared with the first wire segments 1301 that overlap the projections of the shift registers 111, the first wire segments 1301 that overlap the projections of the first signal wires 112 is further away from the display region AA. Since a data fan-out wire 130 needs to be connected to at least one data signal line 120 of the display region AA through the demultiplexing circuit 12, when the data fan-out wire 130 is extended to display region AA, the lengths of different data fan-out wires 130 may be different, which may be simply understood that the lengths of the second wire segments 1302 may be different. In this embodiment, a data signal line 120 connected to a data fan-out wire 130 of which the projection of a first wire segment 1301 overlaps the projection of a first signal wire 112 is configured to be a first data signal line 1201. A data signal line 120 connected to a data fan-out wire 130 of which the projection of a first wire segment 1301 overlaps the projection of a shift register 111 is configured to be a second data signal line 1202. The first data signal line 1201 is configured to be more adjacent to the irregular bezel region NA2 in the arrangement direction of the data signal lines 120, that is, the X direction, so that in the arrangement direction of the data signal lines 120, the data signal line 120 connected to the data fan-out wire 130 of which the projection of the first wire segment 1301 overlaps the projection of the shift register 111 is further away from the irregular bezel region NA2, and the data fan-out wire 130 of which the projection of the first wire segment 1301 overlaps the projection of the first signal wire 112 is more adjacent to the irregular bezel region NA2. In short, in this configuration, the data fan-out wire 1301 of which the projection of the first wire segment 1301 overlaps the projection of the shift register 111 and the data fan-out wire 130 of which the projection of the first wire segment 1301 overlaps the projection of the first signal wire 112 have connection wires of the same length when connecting to the data signal lines 120. Thus, the impedance difference caused by a large difference in the lengths of the connection wires corresponding to the two kinds of data fan-out wires 130 can be avoided. Further, it is possible to ensure that the data signals provided by the two kinds of data fan-out wires 130 to the corresponding data signal lines 120 are more balanced, thereby preventing the problem of uneven display.

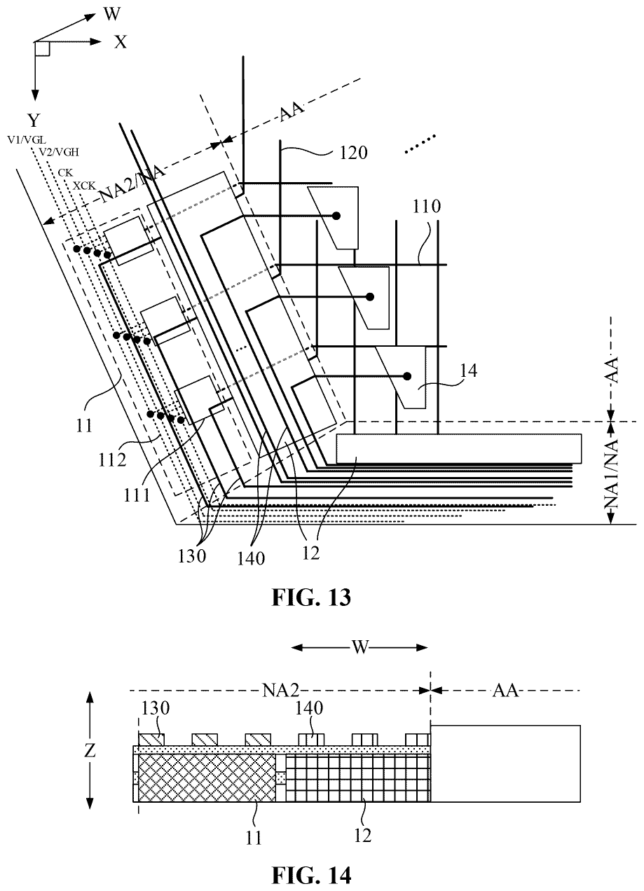

FIG. 12 is a diagram illustrating the structure of another display panel according to an embodiment of the present disclosure. FIG. 13 is a partial enlarged view of the display panel shown in FIG. 12. FIG. 14 is a section view illustrating the partial structure of the display panel shown in FIG. 12. Referring to FIGS. 12 to 14, in other embodiments of the present disclosure, optionally, the display region AA also includes multiple touch electrodes 14. The irregular bezel region NA2 also includes multiple touch fan-out wires 140. The touch fan-out wires are electrically connected to the touch electrodes 14. The touch fan-out wires 140 and the data fan-out wires 130 are located in at least one identical film layer. The projections of the data fan-out wires 130 and the projections of the touch fan-out wires 140 on the light emission surface of the display panel are overlapped with the projection of the shift register circuit 11 and the projection of the demultiplexing circuit 12 on the light emission surface of the display panel.

The touch fan-out wires 140 are responsible for transmitting touch signals, which also need to pass through the irregular bezel region NA2. It is to be understood that due to the presence of the touch fan-out wires 140, the circuit-trace layout of the irregular bezel region NA2 needs to be rationally designed to avoid an excessive area of the irregular bezel region NA2. In this embodiment, for this purpose, the projections of the data fan-out wires 130 and the projections of the touch fan-out wires 140 are configured to be overlapped with the projection of the shift register circuit 11 and the projection of the demultiplexing circuit 12. Essentially, the two kinds of fan-out wires are configured above the shift register circuit 11 and the demultiplexing circuit 12 to implement vertical stacking, thereby alleviating the problem of excessive area of the irregular bezel region NA2 caused by the horizontal layout.

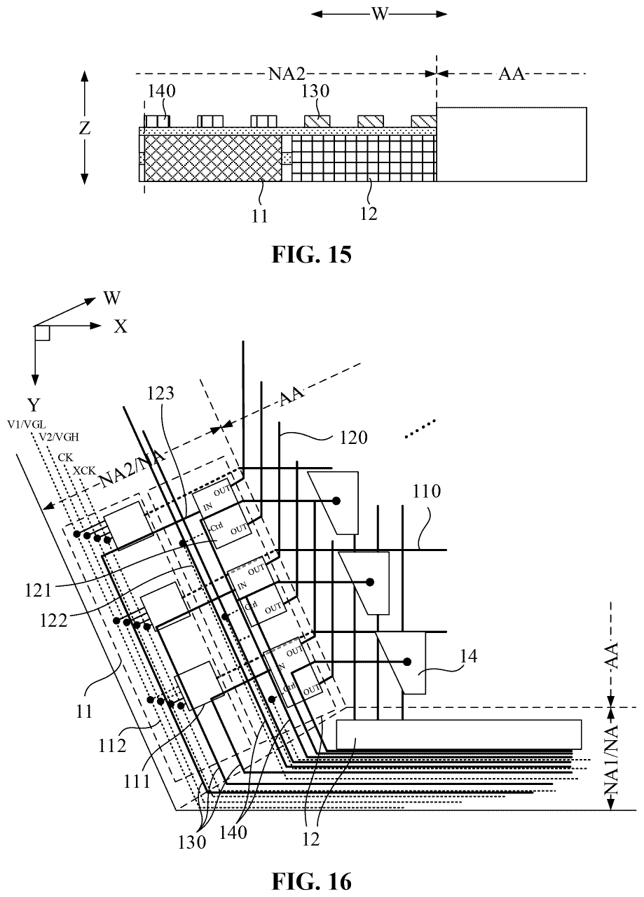

FIG. 15 is a section view illustrating the partial structure of another display panel according to an embodiment of the present disclosure. Compared with FIG. 14 and FIG. 15, it can be seen that in an optional embodiment of the present disclosure, the horizontal left and right positions of the two kinds of fan-out wires, that is, the data fan-out wires 130 and the touch fan-out wires 140, may be adjusted according to actual requirements, and this is not unduly limited in this embodiment.

As shown in FIGS. 13 and 14, in an optional embodiment, the projections of the data fan-out wires 130 on the light emission surface of the display panel may be configured to be overlapped with the projection of the shift register circuit 11 on the light emission surface of the display panel. The projections of the touch fan-out wires 140 on the light emission surface of the display panel are overlapped with the projection of the demultiplexing circuit 12 on the light emission surface of the display panel.

More specifically, as shown in FIGS. 14 and 15, in a specific embodiment, in a third direction W, the region of the projections of the data fan-out wires 130 and the projections of the touch fan-out wires 140 on the light emission surface of the display panel are overlapped with the region of the projection of the shift register circuit 11 and the projection of the demultiplexing circuit 12 on the light emission surface of the display panel. The third direction W is the arrangement direction of the multiple data fan-out wires 130 and the multiple touch fan-out wires 140.

Here, the overlapping of the projection regions in the third direction W means that the edges on two sides in the third direction W overlap respectively. Thus, the edges on two sides of the data fan-out wires 130 and the edges on two sides of the touch fan-out wires 140 in the third direction W are configured to be overlapped with the region of the edges on two sides of the shift register circuit 11 and the edges on two sides of the demultiplexing circuit 12 in the third direction W respectively. Actually, the space of the shift register circuit 11 and the demultiplexing circuit 12 in the third direction W is fully utilized. The data fan-out wires 130 and the touch fan-out wires 140 are configured in this region. Thus, in one aspect, as described above, the data fan-out wires 130 and the touch fan-out wires 140 are prevented from occupying the excessive horizontal area of the irregular bezel region NA2, and in another aspect, it is ensured that the data fan-out wires 130 and the touch fan-out wires 140 have sufficient horizontal wiring space. Two kinds of fan-out wires are configured to have wider line widths and line spacing. Thus, the impedance on a fan-out wire is balanced, and the problem of the excessively small impedance caused by the excessively narrow line width of a signal line is avoided. At the same time, the mutual interference problem caused by excessively close distances of signal lines may also be avoided.

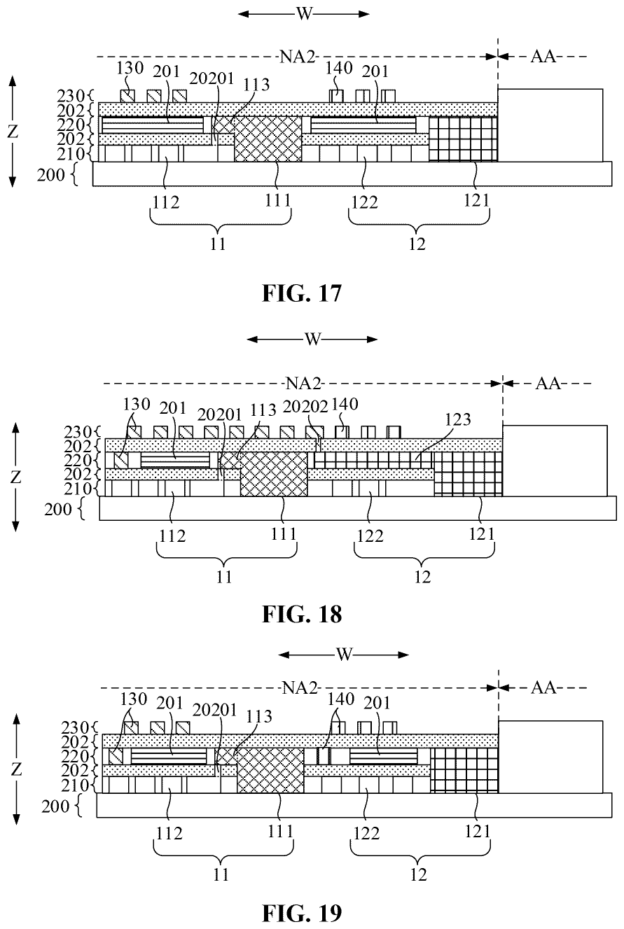

FIG. 16 is a partial view illustrating the structure of another display panel according to an embodiment of the present disclosure. FIG. 17 is a section view illustrating the partial structure of the display panel shown in FIG. 16. Referring to FIGS. 16 and 17, specifically, the source driver circuit 12 includes multiple demultiplexers 121 and multiple second signal wires 122 located on the side of the demultiplexers 121 facing away from the display region AA.

A demultiplexer 121 includes a control terminal Ctrl, an input terminal IN, and at least two output terminals OUT. The control terminal Ctrl is connected to a second signal wire 122. The input terminal IN is connected to a data fan-out wire 130. An output terminal OUT is connected to a data signal line 120.

The touch fan-out wires 140 and the second signal wires 122 are located in different film layers of the display panel, and a signal shielding layer 201 is configured between the film layer where the touch fan-out wires 140 are located and the film layer where the second signal wires 122 are located.

The demultiplexer 121 is essentially a selector and may be specifically a transistor or a MOS transistor. In this embodiment, the demultiplexer 121 has two output terminals OUT, that is, connecting two data signal lines 120 is only an example. It should be understood by those skilled in the art that in the actual application process, the demultiplexer 121 may be provided with three, four, or six output terminals to implement source driving in one demultiplexer driving three data signal lines, one demultiplexer driving four data signal lines, and one demultiplexer driving six data signal lines manner.

Similarly, further referring to FIG. 17, the display panel also includes a base substrate 200, a first metal layer 210, a second metal layer 220, and a third metal layer 230. In the direction perpendicular to the plane where the base substrate 200 is located and away from the base substrate 200, the first metal layer 210, the second metal layer 220, and the third metal layer 230 are distributed on the side of the base substrate 200 in sequence. The interlayer insulating layer 202 is configured between two adjacent layers of the first metal layer 210, the second metal layer 220, and the third metal layer 230. The touch fan-out wires 140 are located in the third metal layer 230. The second signal wires 122 are located in the first metal layer 210. The signal shielding layer 201 is located in the second metal layer 220.

The principle here is the same as the principle of the preceding embodiment in which the signal shielding layer 201 is configured between the data fan-out wires 130 and the first signal wires 112 in the shift register circuit 11. The interference of high-frequency signals such as strobe signals in the second signal wires 122 to the touch signals transmitted on the touch fan-out wires 140 is shielded by the signal shielding layer 201. Thus, the normal transmission of the touch signals on the touch fan-out wires 140 may be ensured, thereby ensuring that the touch detection is accurate. Moreover, the signal shielding layer 201 may also be configured in the second metal layer 220. Thus, the addition of a metal layer to the signal shielding layer 201 alone is avoided. Further, the preparation process and the preparation technique of the display panel may be simplified, and on the premise that the signal shielding layer 201 is used to shield the touch fan-out wires 140 from interference, the manufacturing costs can be saved.

Similarly, to implement a better shielding effect, for example, in the preceding embodiment, for the signal shielding layer 201 between the touch fan-out wires 140 and the second signal wires 122, a fixed potential signal may be introduced into the signal shielding layer 201.

Specifically, further referring to FIG. 6, in an embodiment of the present disclosure, the first signal wires 112 include first level signal lines V1 and second level signal lines V2. The potential on a first level signal line V1 is less than the potential on a second level signal line V2. The first level signal lines V1 or the second level signal lines V2 may be electrically connected to the signal shielding layer 201. The first level signal lines V1 may be understood as low-level signal lines VGL in the shift register circuit 11. The second level signal lines V2 may be understood as high-level signal lines VGH in the shift register circuit 11. In this embodiment, essentially, the logic high-level signal or logic low-level signal in the shift register circuit 11 is introduced into the signal shielding layer 201 to stabilize the potential of the signal shielding layer 201.

Further referring to FIG. 9, in another embodiment of the present disclosure, the non-display region NA also includes a bonding pad 13 and a fixed potential signal line 150. The bonding pad 13 is configured to bond a driver chip IC.

One end of the fixed potential signal line 150 is electrically connected to the signal shielding layer 201, and the other end of the fixed potential signal line 150 is electrically connected to the driver chip IC through the bonding pad 13. The driver chip IC is configured to provide the fixed potential signal to the signal shielding layer 201 through the fixed potential signal line 150.

In the preceding two embodiments, a fixed potential signal is introduced into the signal shielding layer 201, so that the signal shielding layer 201 may have a stable potential. Thus, the electromagnetic interference generated by a high-frequency signal is shielded, so that the signal shielding layer 201 can effectively block the electromagnetic interference generated by the first signal wires 112 to the data fan-out wires 130.

FIGS. 18 and 19 are section views illustrating the partial structures of another two display panels according to an embodiment of the present disclosure. Referring to FIGS. 18 and 19, the display panel also includes a base substrate 200, a first metal layer 210, a second metal layer 220, and a third metal layer 230. In the direction perpendicular to the plane where the base substrate 200 is located and away from the base substrate 200, the first metal layer 210, the second metal layer 220, and the third metal layer 230 are distributed on the side of the base substrate 200 in sequence. The interlayer insulating layer 202 is configured between two adjacent layers of the first metal layer 210, the second metal layer 220, and the third metal layer 230. In other embodiments of the present disclosure, optionally, at least part of the data fan-out wires 130 and at least part of touch fan-out wires 140 are located in the third metal layer 120.

Specifically, referring to FIG. 18, the irregular bezel region NA2 also includes multiple second connection wires 123 located in the second metal layer 220. One end of a second connection wire 123 is electrically connected to a data fan-out wire 130 located in the third metal layer 230 through a second via 20202, and the other end of the second connection wire 123 is electrically connected to the demultiplexing circuit 12. The second via 20202 is located in an interlayer insulating layer 202 between the second metal layer 220 and the third metal layer 230. Furthermore, the projection of the second via 20202 on the light emission surface of the display panel is located between the projection of the shift register circuit 11 and the projection of the demultiplexing circuit 12 on the light emission surface of the display panel. As shown in FIG. 18, when the data fan-out wires 130 and the touch fan-out wires 140 are configured in the third metal layer 230 at the same time, and the data fan-out wires 130 are disposed above the shift register circuit 11, to electrically connect the data fan-out wires 130 to the demultiplexing circuit 12, a via, that is, a second via 20202, may be disposed between the shift register circuit 11 and the demultiplexing circuit 12. The second connection lines 123 are disposed in the second metal layer 220 so that the data fan-out wires 130 are connected to the demultiplexing circuit 12.

Further referring to FIG. 19, in a specific embodiment, part of the data fan-out wires 130 may also be configured to be located in the second metal layer 220, and part of the data fan-out wires 130 are located in the third metal layer 230; and/or part of the touch fan-out wires 140 are located in the second metal layer 220, and part of the touch fan-out wires 140 are located in the third metal layer 230. FIG. 19 only illustrates the case where the data fan-out wires 130 and the touch fan-out wires 140 are simultaneously arranged in the second metal layer 220 and the third metal layer 230. Those skilled in the art may select to arrange only the data fan-out wires 130 in the second metal layer 220 and the third metal layer 230 at the same time or select to arrange only the touch fan-out wires 140 in the second metal layer 220 and the third metal layer 230 at the same time according to actual requirements. This is not limited in this embodiment.

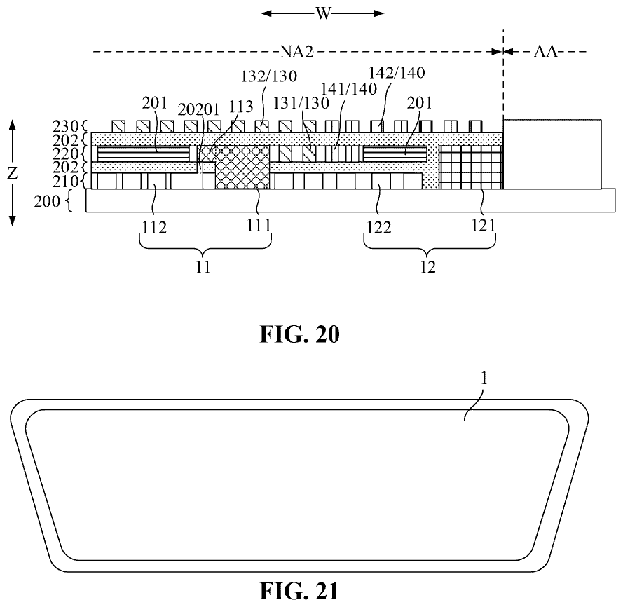

FIG. 20 is a section view illustrating the partial structure of another display panel according to an embodiment of the present disclosure. Referring to FIG. 20, furthermore, in another embodiment of the present disclosure, optionally, the data fan-out wires 130 include first data fan-out wires 131 and second data fan-out wires 132; and/or the touch fan-out wires 140 include first touch fan-out wires 141 and second touch fan-out wires 142.

The first data fan-out wires 131 are located in the second metal layer 220. The second data fan-out wires 132 are located in the third metal layer 230. The projections of the first data fan-out wires 131 on the light emission surface of the display panel are located between the projection of the shift register circuit 11 and the projection of the demultiplexing circuit 12 on the light emission surface of the display panel and in the projections of the second data fan-out wires 132 on the light emission surface of the display panel.

The first touch fan-out wires 141 are located in the second metal layer 220. The second touch fan-out wires 142 are located in the third metal layer 230. The projections of the first touch fan-out wires 141 on the light emission surface of the display panel are between the projection of the shift register circuit 11 and the projection of the demultiplexing circuit 12 on the light emission surface of the display panel and in the projections of the second touch fan-out wires 142 on the light emission surface of the display panel.

The first data fan-out wires 131 may be understood as data fan-out wires 130 disposed in the second metal layer 220. The first touch fan-out wires 141 may be understood as touch fan-out wires 140 disposed in the second metal layer 220. The difference from the data fan-out wires 130 and the touch fan-out wires 140 disposed in the second metal layer 220 shown in FIG. 19 lies in that in this embodiment, the first data fan-out wires 131 are located between the shift register circuit 11 and the demultiplexing circuit 12 and do not overlap the projection of the shift register circuit 11 and the projection of the demultiplexing circuit 12. Similarly, in this embodiment, the first touch fan-out wires 141 are also located between the shift register circuit 11 and the demultiplexing circuit 12 and do not overlap the projection of the shift register circuit 11 and the projection of the demultiplexing circuit 12. It is to be noted that in this embodiment, the data fan-out wires 130 and the touch fan-out wires 140 are disposed in the second metal layer 220 and are disposed between the shift register circuit 11 and the demultiplexing circuit 12. It is mainly applied to the case where there are too many data fan-out wires 130 or too many touch fan-out wires 140 in the irregular bezel region NA2, the horizontal width of the shift register circuit 11 and the horizontal width of the demultiplexing circuit 12 are small, all the data fan-out wires 130 and the touch fan-out wires 140 cannot be disposed in the third metal layer 230, and a projection is located in the projection of the shift register circuit 11 and the projection of the demultiplexing circuit 12. In other words, when there are too many data fan-out wires 130 or too many touch fan-out wires 140 in the irregular bezel region NA2, and as a result, all of them are disposed in the same layer, the region of the projections of the data fan-out wires 130 and the projections of the touch fan-out wires 140 may be larger than the region of the projection of the shift register circuit 11 and the projection of the demultiplexing circuit 12. Based on this, the redundant data fan-out wires 130 or touch fan-out wires 140 which cannot be contained in the region of the projection of the shift register circuit 11 and the projection of the demultiplexing circuit 12 are arranged in two metal layers, that is, the second metal layer 220 and the third metal layer 230. The projection area of the redundant data fan-out wires 130 and the projection area of the redundant touch fan-out wire 140 may be reduced as much as possible, that is, the width of the irregular bezel region NA2 may be reduced as much as possible, thereby implementing the design of a narrow bezel.

Similarly, FIG. 20 only illustrates the case where the data fan-out wires 130 and the touch fan-out wires 140 are simultaneously arranged in the second metal layer 220 and the third metal layer 230, that is, there are too many data fan-out wires 130 and touch fan-out wires 140. For actual requirements, when there are only too many data fan-out wires 130 or only too many touch fan-out wires 140, only the data fan-out wires 130 are arranged in the second metal layer 220 and the third metal layer 230 at the same time, or only the touch fan-out wires 140 are arranged in the second metal layer 220 and the third metal layer 230 at the same time. This is not limited in this embodiment.

In addition, it is added that in the embodiment shown in FIGS. 19 and 20, since part of the data fan-out wires 130 and part of the touch fan-out wires 140 are disposed in the second metal layer 120, and as described above, there are signal lines in the second signal wires 122 that need to transmit pulse signals, to avoid capacitive coupling of the data fan-out wires 130 and the touch fan-out wires 140 located in the second metal layer 220 by the pulse signals in the second signal wires 122, referring to the embodiment shown in FIG. 10 and FIG. 11, the interlayer insulating layer 202 between the first metal layer 210 and the second metal layer 220 is thickened. Alternatively, a material having a smaller dielectric constant is used for preparation to reduce the coupling capacitance between the wires of the first metal layer 210 and the second metal layer 220 and avoid interference between signals.

Based on the same concept, an embodiment of the present disclosure provides a display device. FIG. 21 is a diagram illustrating the structure of a display device according to an embodiment of the present disclosure. Referring to FIG. 21, the display device includes the display panel 1 provided by any embodiment of the present disclosure. Thus, the display device according to this embodiment of the present disclosure has correspondingly beneficial effects of the display panel according to the embodiments of the present disclosure, and the details are not repeated here. For example, the display device may be an in-vehicle display device and other electronic devices, such as an in-vehicle electronic rear-view mirror, an electronic instrument panel, and a central control panel. This is not limited in this embodiment of the present disclosure.

It is to be noted that the preceding are only preferred embodiments of the present disclosure and the technical principles used therein. It is to be understood by those skilled in the art that the present disclosure is not limited to the embodiments described herein. For those skilled in the art, various apparent modifications, adaptations, combinations, and substitutions can be made without departing from the scope of the present disclosure. Therefore, while the present disclosure is described in detail in connection with the preceding embodiments, the present disclosure is not limited to the preceding embodiments and may include equivalent embodiments without departing from the concept of the present disclosure. The scope of the present disclosure is determined by the scope of the appended claims.

What is claimed is:

1. A display panel, comprising a display region and a non-display region, wherein the non-display region and the display region are connected to each other, and the display region comprises a plurality of data signal lines and a plurality of scanning signal lines, and the plurality of data signal lines intersect the plurality of scanning signal lines;
the non-display region comprises an irregular bezel region, and a boundary line between the irregular bezel region and the display region intersects extension lines of the plurality of data signal lines and extension lines of the plurality of scanning signal lines; and the irregular bezel region comprises a gate driver circuit region and a source driver circuit region, and the source driver circuit region is located between the gate driver circuit region and the display region;
a shift register circuit is configured in the gate driver circuit region, and the shift register circuit is electrically connected to the plurality of scanning signal lines and configured to provide a gate drive signal to the plurality of scanning signal lines in sequence;
a demultiplexing circuit is configured in the source driver circuit region, and the demultiplexing circuit is electrically connected to the plurality of data signal lines and configured to provide a data signal to the plurality of data signal lines in sequence;
the irregular bezel region further comprises a plurality of data fan-out wires, and one of the plurality of data fan-out wires is electrically connected to at least two of the plurality of data signal lines through the demultiplexing circuit; and
the plurality of data fan-out wires and the shift register circuit are located in different film layers of the display panel, the plurality of data fan-out wires and the demultiplexing circuit are located in different film layers of the display panel, and projections of the plurality of data fan-out wires on a light emission surface of the display panel are overlapped with at least one of a projection of the shift register circuit and a projection of the demultiplexing circuit on the light emission surface of the display panel.

2. The display panel according to claim 1, wherein the shift register circuit comprises a plurality of shift registers and a plurality of first signal wires;
the plurality of shift registers are cascaded in sequence, the plurality of first signal wires extend in parallel and located on one side of the plurality of shift registers facing away from the display region, and one of the plurality of shift registers is electrically connected to at least one of the plurality of first signal wires; and
the projections of the plurality of data fan-out wires on the light emission surface of the display panel are overlapped with projections of the plurality of shift registers and/or projections of the plurality of first signal wires on the light emission surface of the display panel.

3. The display panel according to claim 2, wherein the projections of the plurality of data fan-out wires on the light emission surface of the display panel are overlapped with the projections of the plurality of first signal wires on the light emission surface of the display panel; and
the plurality of data fan-out wires and the plurality of first signal wires are located in different film layers of the display panel, and a signal shielding layer is disposed between a film layer where the plurality of data fan-out wires are located and a film layer where the plurality of first signal wires are located;
wherein a fixed potential signal is received by a signal shielding layer.

4. The display panel according to claim 3, further comprising: a base substrate, a first metal layer, a second metal layer, and a third metal layer;
wherein in a direction perpendicular to a plane where the base substrate is located and away from the base substrate, the first metal layer, the second metal layer, and the third metal layer are distributed on one side of the base substrate in sequence; and an interlayer insulating layer is disposed between two adjacent layers of the first metal layer, the second metal layer, and the third metal layer; and
the plurality of data fan-out wires are located in the third metal layer, the plurality of first signal wires are located in the first metal layer, and the signal shielding layer is located in the second metal layer.

5. The display panel according to claim 4, wherein the shift register circuit comprises a plurality of first connection wires located in the second metal layer;
one end of one of the plurality of first connection wires is electrically connected to the one shift register, another end of the one first connection wire is electrically connected to one of the plurality of first signal wires through a first via, and the first via is located in an interlayer insulating layer between the first metal layer and the second metal layer; and
a projection of the signal shielding layer on the light emission surface of the display panel does not overlap projections of the plurality of first connection wires on the light emission surface of the display panel.

6. The display panel according to claim 2, further comprising a base substrate, a first metal layer, a second metal layer, and a third metal layer;
wherein in a direction perpendicular to a plane where the base substrate is located and away from the base substrate, the first metal layer, the second metal layer, and the third metal layer are distributed on one side of the base substrate in sequence;
an interlayer insulating layer is disposed between two adjacent layers of the first metal layer, the second metal layer, and the third metal layer; and
the plurality of first signal wires are located in the first metal layer, and at least part of the plurality of data fan-out wires are located in the second metal layer.

7. The display panel according to claim 6, wherein the interlayer insulating layer comprises a first interlayer insulating layer and a second interlayer insulating layer, the first interlayer insulating layer is located between the first metal layer and the second metal layer, and the second interlayer insulating layer is located between the second metal layer and the third metal layer; and
a thickness of the first interlayer insulating layer is greater than a thickness of the second interlayer insulating layer, and/or a dielectric constant of the first interlayer insulating layer is less than a dielectric constant of the second interlayer insulating layer.

8. The display panel according to claim 2, wherein the plurality of data fan-out wires comprise first wire segments, and an extension direction of the first wire segments is parallel to an extension direction of a junction line between the irregular bezel region and the display region;
projections of first wire segments of part of the plurality of data fan-out wires on the light emission surface of the display panel are overlapped with the projections of the plurality of shift registers on the light emission surface of the display panel; and projections of first wire segments of part of the plurality of data fan-out wires on the light emission surface of the display panel are overlapped with the projections of the plurality of first signal wires on the light emission surface of the display panel;
the plurality of data signal lines comprises first data signal lines and second data signal lines, a data fan-out wire of which a projection of a first wire segment overlaps a projection of a first signal wire is electrically connected to a first data signal line of the first data signal lines through the demultiplexing circuit, and a data fan-out wire of which the projection of the first wire segment overlaps a projection of a shift register is electrically connected to a second data signal line of the second data signal lines through the demultiplexing circuit; and
in a first direction, the first data signal lines are located on a side of the second data signal lines closest the irregular bezel region, wherein the first direction is an arrangement direction of the plurality of data signal lines.

9. The display panel according to claim 1, wherein the display region further comprises a plurality of touch electrodes, the irregular bezel region further comprises a plurality of touch fan-out wires, and the plurality of touch fan-out wires are electrically connected to the plurality of touch electrodes; and
the plurality of touch fan-out wires and the plurality of data fan-out wires are located in at least one identical film layer, and the projections of the plurality of data fan-out wires and projections of the plurality of touch fan-out wires on the light emission surface of the display panel are overlapped with the projection of the shift register circuit and the projection of the demultiplexing circuit on the light emission surface of the display panel.

10. The display panel according to claim 9, wherein the projections of the plurality of data fan-out wires on the light emission surface of the display panel are overlapped with the projection of the shift register circuit on the light emission surface of the display panel; and the projections of the plurality of touch fan-out wires on the light emission surface of the display panel are overlapped with the projection of the demultiplexing circuit on the light emission surface of the display panel.

11. The display panel according to claim 10, wherein the source driver circuit comprises a plurality of demultiplexers and a plurality of second signal wires located on one side of the plurality of demultiplexers facing away from the display region;
each of the plurality of demultiplexers comprises a control terminal, an input terminal, and at least two output terminals, the control terminal is connected to one of the plurality of second signal wires, the input terminal is connected to one of the plurality of data fan-out wires, and one of the at least two output terminals is connected to one of the plurality of data signal lines; and
the plurality of touch fan-out wires and the plurality of second signal wires are located in different film layers of the display panel, and a signal shielding layer is disposed between a film layer where the plurality of touch fan-out wires are located and a film layer where the plurality of second signal wires are located;
wherein a fixed potential signal is received by a signal shielding layer.

12. The display panel according to claim 11, further comprising a base substrate, a first metal layer, a second metal layer, and a third metal layer;
wherein in a direction perpendicular to a plane where the base substrate is located and away from the base substrate, the first metal layer, the second metal layer, and the third metal layer are distributed on one side of the base substrate in sequence; and an interlayer insulating layer is disposed between two adjacent layers of the first metal layer, the second metal layer, and the third metal layer; and
the plurality of touch fan-out wires are located in the third metal layer, the plurality of second signal wires are located in the first metal layer, and the signal shielding layer is located in the second metal layer.

13. The display panel according to claim 9, wherein further comprising a base substrate, a first metal layer, a second metal layer, and a third metal layer;
wherein in a direction perpendicular to a plane where the base substrate is located and away from the base substrate, the first metal layer, the second metal layer, and the third metal layer are distributed on a side of the base substrate in sequence; and an interlayer insulating layer is disposed between two adjacent layers of the first metal layer, the second metal layer, and the third metal layer; and
at least part of the plurality of data fan-out wires and at least part of the plurality of touch fan-out wires are located in the third metal layer.

14. The display panel according to claim 13, wherein the irregular bezel region further comprises a plurality of second connection wires located in the second metal layer; and
one end of each second connection wire of the plurality of second connection wires is electrically connected to a data fan-out wire of the plurality of data fan-out wires located in the third metal layer through a second via, another end of the each second connection wire is electrically connected to the demultiplexing circuit, and the second via is located in an interlayer insulating layer between the second metal layer and the third metal layer.

15. The display panel according to claim 14, wherein a projection of the second via on the light emission surface of the display panel is located between the projection of the shift register circuit and the projection of the demultiplexing circuit on the light emission surface of the display panel.

16. The display panel according to claim 13, wherein part of the plurality of data fan-out wires are located in the second metal layer, and part of the plurality of data fan-out wires are located in the third metal layer; and/or part of the plurality of touch fan-out wires are located in the second metal layer, and part of the plurality of touch fan-out wires are located in the third metal layer.

17. The display panel according to claim 13, wherein the plurality of data fan-out wires comprise first data fan-out wires and second data fan-out wires, the first data fan-out wires are located in the second metal layer, and the second data fan-out wires are located in the third metal layer;
projections of the first data fan-out wires on the light emission surface of the display panel is located between the projection of the shift register circuit and the projection of the demultiplexing circuit on the light emission surface of the display panel and in projections of the second data fan-out wires on the light emission surface of the display panel; and/or
the plurality of touch fan-out wires comprise first touch fan-out wires and second touch fan-out wires, the first touch fan-out wires are located in the second metal layer, and the second touch fan-out wires are located in the third metal layer; and
projections of the touch data fan-out wires on the light emission surface of the display panel is located between the projection of the shift register circuit and the projection of the demultiplexing circuit on the light emission surface of the display panel and in projections of the second touch fan-out wires on the light emission surface of the display panel.

18. The display panel according to claim 9, wherein in a third direction, a first region is a region in which the projections of the plurality of data fan-out wires and the projections of the plurality of touch fan-out wires on the light emission surface of the display panel are located, a second region is a region in which the projection of the shift register circuit and the projection of the demultiplexing circuit on the light emission surface of the display panel, and the first region overlaps the second region in the third direction, wherein the third direction is an arrangement direction of the plurality of data fan-out wires and the plurality of touch fan-out wires.

19. The display panel according to claim 3, wherein the shift register circuit comprises a plurality of shift registers and a plurality of first signal wires;
wherein the plurality of shift registers are cascaded in sequence, the plurality of first signal wires extend in parallel and located on a side of the plurality of shift registers facing away from the display region, and one of the plurality of shift registers is electrically connected to at least one of the plurality of first signal wires;
the plurality of first signal wires comprise first level signal lines and second level signal lines, and a potential on one of the first level signal lines is less than a potential on one of the second level signal lines; and
the first level signal lines or the second level signal lines are electrically connected to the signal shielding layer.

20. A display device, comprising a display panel, wherein the display panel comprises:
a display region and a non-display region, wherein the non-display region and the display region are connected to each other, and the display region comprises a plurality of data signal lines and a plurality of scanning signal lines, and the plurality of data signal lines intersect the plurality of scanning signal lines;
the non-display region comprises an irregular bezel region, and a boundary line between the irregular bezel region and the display region intersects extension lines of the plurality of data signal lines and extension lines of the plurality of scanning signal lines; and the irregular bezel region comprises a gate driver circuit region and a source driver circuit region, and the source driver circuit region is located between the gate driver circuit region and the display region;
a shift register circuit is configured in the gate driver circuit region, and the shift register circuit is electrically connected to the plurality of scanning signal lines and configured to provide a gate drive signal to the plurality of scanning signal lines in sequence;
a demultiplexing circuit is configured in the source driver circuit region, and the demultiplexing circuit is electrically connected to the plurality of data signal lines and configured to provide a data signal to the plurality of data signal lines in sequence;
the irregular bezel region further comprises a plurality of data fan-out wires, and one of the plurality of data fan-out wires is electrically connected to at least two of the plurality of data signal lines through the demultiplexing circuit; and
the plurality of data fan-out wires and the shift register circuit are located in different film layers of the display panel, the plurality of data fan-out wires and the demultiplexing circuit are located in different film layers of the display panel, and projections of the plurality of data fan-out wires on a light emission surface of the display panel are overlapped with at least one of a projection of the shift register circuit and a projection of the demultiplexing circuit on the light emission surface of the display panel.
